(19) United States
(12) Patent Application Publication
(10) Pub. No.: US 2005/0157894 A1
(43) Pub. Date: Jul. 21, 2005

(54) Sound feature positioner

(76) Inventors: Anthony J. Andrews, Surrey (GB); John Newsham, Surrey (GB)

Correspondence Address: ANDRUS, SCEALES, STARKE & SAWALL, LLP, 100 EAST WISCONSIN AVENUE, SUITE 1100, MILWAUKEE, WI, 53202, US

(21) Appl. No.: 11/034,221

(22) Filed: Jan. 12, 2005

(30) Foreign Application Priority Data
Jan. 16, 2004 (GB) 0400931.2

(51) Int. Cl. H04R 5/02; H03G 5/00

(52) U.S. Cl. 381/307; 381/98

(57) ABSTRACT

A music signal is supplied to a bandpass filter. The output of the filter is supplied to a first channel of a surround sound encoder and the music signal is supplied to a second channel of the encoder. The encoded signal is supplied to a surround sound decoder and then to an array of loudspeakers for creating a soundfield in a venue. The filter extracts sufficient of the sound of, for example, a musical instrument and the encoder allows the apparent location or direction of the extracted instrument to be placed and moved with respect to the soundfield.

### TECHNICAL FIELD

The present invention relates to a sound feature positioner.

### BACKGROUND

Various types of surround sound encoder/decoder arrangements are known for creating a soundfield with individual sound sources appearing to be located within the soundfield or to emanate from different directions around a listener. A particular example of such an arrangement is known under the title of “Ambisonics” and a considerable amount of information is available on a website organised by the University of York at http://www.york.ac.uk/inst/mustech/3d_audio/ambis2.htm. The website includes a listing of published references relating to the Ambisonic system and the reference list is as follows:
D. H. Cooper & T. Shiga, ‘Discrete-Matrix Multichannel Stereo,’ J. Audio Eng. Soc., vol. 20 pp. 346-360 (1972 June) Correction ibid vol. 20 p. 493 (1972 July/August) (Basic paper on the Hierarchical ideas refined in Ambisonics)
0. Kohsaka, E. Satoh & T. Nakayama, ‘Sound Image Localization in Multichannel Matrix Reproduction,’ J. Audio Eng. Soc., vol. 20 pp. 542-548 (1972 September) (Early experimental confirmation of the improved sound localisation of systems based on Ambisonic ideas).
P. B. Fellgett, ‘Directional Information in Reproduced Sound,’ Wireless World, vol. 78, pp. 413-417 (1972 September) (One of several papers coming up with Ambisonic ideas at that time.)
J. J. Gibson, R. M. Christensen & A. L. R. Limberg, ‘Compatible FM Broadcasting of Panoramic Sound’, J. Audio Eng. Soc., vol. 20 pp. 816-822 (1972 December). (Although primarily about FM broadcast methods for surround-sound, this paper describes the hierarchical approach both for horizontal and with-height surround sound based on directional harmonics and spherical harmonics also used in Ambisonics)
M. A. Gerzon, ‘Periphony: With-Height Sound Reproduction’, J. Audio Eng. Soc., vol. 21, pp. 2-10 (1973 January/February) (A highly mathematical account of general with-height reproduction systems. Includes the fundamental theory of with-height directional encoding systems).
Michael Gerzon, ‘Surround Sound Psychoacoustics’, Wireless World, vol. 80, pp. 483-486 (1974 December) (The first, and clearest, publication of the psychoacoustic decoding theory behind Ambisonic decoding)
Michael Gerzon, ‘What's Wrong with Quadraphonics?’, Studio Sound, vol. 16 no. 5, pp. 50, 51, 56 (1974 May)
M. A. Gerzon, ‘A Geometric Model for Two-Channel Four-Speaker Matrix Stereo Systems’, J. Audio Eng. Soc., vol. 23, pp. 98-106 (1975 March)
M. A. Gerzon, ‘The Design of Precisely Coincident Microphone Arrays for Stereo and Surround Sound’, preprint of the 50th Audio Engineering Society Convention, London (1975 March) (About the design of the SoundField microphone)
Peter Fellgett, ‘Ambisonics. Part One. General System Description’, Studio Sound, vol. 17 no. 8, pp. 20-22, 40 (1975 August)
Michael Gerzon, ‘Ambisonics. Part Two: Studio Techniques’, Studio Sound, vol. 17 no. 8, pp. 24, 26, 28-30 (1975 August) Correction: Studio Sound, vol. 17 no. 10, p. 60 (1975 Oct.)
M. A. Gerzon, ‘Recording Concert Hall Acoustics for Posterity’, J. Audio Eng. Soc., vol. 23, pp. 569, 571 (1975 September) (Describes the use of soundfield microphone recordings of hall impulse responses to simulate reverberant spaces Ambisonically)
P. B. Fellgett & M. A. Gerzon, ‘Encoding Standards for 2-Channel Surround-Sound’, Electronics Letters, vol. 11, pp. 518-519 (1975 Oct. 16) (A summary of the basic ideas behind optimising 2-channel surround sound encoding systems.)
M. A. Gerzon, ‘Compatible 2-Channel Encoding of Surround Sound’, Electronics Letters, vol. 11, pp. 615-617 (1975 Dec. 11) (A summary of the details for optimising 2-channel surround sound encoding systems.)
M. A. Gerzon, ‘Maximum Directivity Factor of n'th-Order Transducers’, J. Acoust. Soc. Am., vol. 60, pp. 278-280 (1976 July) (A mathematical proof of results about the directivity of high order microphones, relevant to periphony.)
M. A. Gerzon, ‘The Optimum Choice of Surround-Sound Encoding Specification’, Preprint no. 1199 of the 56th Audio Engineering Society Convention, Paris, (1977 Mar. 1) (About optimising 2-channel encoding for surround-sound—the theory behind UHJ. Very mathematical)
Michael Gerzon, ‘NRDC Surround-Sound System’, Wireless World, vol. 83 no. 1496, pp. 36-39 (1977 April) (A non-technical account of the work in the previous reference.)
P. Fellgett & M. Gerzon, ‘From quadro to surround sound’, Elektor, vol. 3 no. 5, no. 25, pp. 5-19 to 5-25 (1977 May)
M. A. Gerzon, ‘Criteria for Evaluating Surround-Sound Systems’, J. Audio Eng. Soc., vol. 25, pp. 400-408 (1977 June) (Although containing a lot of now-historic references to quadraphonics, this is still the best summary of the underlying philosophy of Ambisonics. Concentrates on the ideas, not on technical details.)
Michael Gerzon, ‘Multi-System Ambisonic Decoder’, Part 1: ‘Basic Design Philosophy’, Wireless World, vol. 83 no. 1499, pp. 43-47 (1977 July) Part 2: ‘Main Decoder Circuits’, Wireless World, vol. 83 no. 1500, pp. 69-73 (1977 August) later parts never written & published.
Michael Gerzon, ‘Don't say quad—say psychoacoustics’, New Scientist, vol. 76, pp. 634-636 (1977 Dec. 8)
J. H. Smith, ‘The Soundfield Microphone,’ dB, pp. 34-37 (1978 July)
P. S. Gaskell, ‘System UHJ: A Hierarchy of Surround Sound Transmission Systems,’ Radio & Electron. Eng., vol. 49, pp. 449-459 (1979 September)
K. Farrar, ‘Soundfield Microphone,’ Wireless World, vol. 85 pp. 48-50 (1979 October) and pp. 99-103 (1979 November) (Best published reference on the design of the Soundfield microphone.)
M. A. Gerzon, ‘Pictures of 2-Channel Directional Reproduction Systems’, Preprint 1569 of the 65th Audio Engineering Society Convention, London (1980 February)
M. A. Gerzon, ‘Practical Periphony’, Preprint 1571 of the 65th Audio Engineering Society Convention, London (1980 February) (A relatively non-technical account of practical with-height full-sphere Ambisonic decoding).
John Borwick, Audio Commentary ‘Could ‘Surround Sound’ Bounce Back?’, The Gramophone, 1981 Feb., 2 pages.
P B Fellgett, ‘Ambisonics’, New Electronics, 1981 May, pp. 38, 44, 46 and 48.
C. P. Daubney, ‘Surround Sound: An Operational Insight,’ IBA Tech. Rev., no. 14 pp. 52-56 (1981 June): reprinted in Studio Sound, vol. 24, pp. 52-54, 56, 58 (1982 August)
T. de Bono, ‘Gilgamesh, The Epic of the Epic,’ Broadcast Sound, pp. 10-12, 15 (1983 January/February)
Richard Elen, ‘Ambisonic Mixing—An Introduction,’ Studio Sound, vol. 25 pp. 40-42, 44, 46 (1983 September)
Nigel Branwell, ‘Ambisonic Surround-Sound Technology for Recording and Broadcast’, Recording Engineer/Producer, December 1983, 4 pages.
M. A. Gerzon & G. J. Barton, ‘Ambisonic Surround-Sound Mixing for Multitrack Studios’, Conference Paper C1009 of the 2nd Audio Engineering Society International Conference, Anaheim (1984 May 11-14) (Describes commercially available studio production technology for Ambisonics using multitrack methods).
M. A. Gerzon, ‘Ambisonics in Multichannel Broadcasting and Video’, J. Audio Eng. Soc., vol. 33 no. 11, pp. 859-871 (1985 November) (Possibly the best overview of classic Ambisonics.)
Michael Gerzon, ‘Three Channels. The Future of Stereo?’, Studio Sound, vol. 32 no. 6, pp. 112, 114, 117, 118, 120, 123 & 125 (1990 June) (An account of Ambisonic ideas applied to 3-speaker frontal stereo.)
M. A. Gerzon, ‘Masking of Coding/Decoding Errors in Audio Data Compression’, Proc. Inst. of Acoustics, vol. 12 part 8, pp. 175-182 (1990 November)
M. A. Gerzon, ‘Problems of Error-Masking in Audio Data Compression Systems’, Preprint 3013 of the 90th Audio Engineering Society Convention, Paris (1991 February) (A technical discussion including the problems of ‘directional unmasking’ of error artefacts in perceptual coding systems for surround sound.)
M. A. Gerzon, ‘Hierarchical Transmission of Multispeaker Stereo’, Proceedings of the IEEE ASSP Workshop on Applications of Signal Processing to Audio and Acoustics, New Paltz, N.Y., (1991 Oct. 20-23)
M. A. Gerzon, ‘Directional Masking Coders for Multichannel Subband Audio Data Compression Systems’, Preprint 3261 of the 92nd Audio Engineering Society Convention, Vienna (1992 March) (A technical discussion concentrating on methods of ‘directional masking’ of error artefacts in perceptual coding systems for surround sound.)
M. A. Gerzon, ‘General Metatheory of Auditory Localisation’, Preprint 3306 of the 92nd Audio Engineering Society Convention, Vienna (1992 March) (This is THE basic reference, mostly written in 1976, for the psychoacoustic theory behind Ambisonics. Highly technical and mathematical, but fundamental to design of Ambisonic decoders.)
M. A. Gerzon, ‘The Design of Distance Panpots’, Preprint 3308 of the 92nd Audio Engineering Society Convention, Vienna (1992 March) (Simulating distance effects in directional reporoduction.)
M. A. Gerzon, ‘Panpot Laws for Multispeaker Stereo’, Preprint 3309 of the 92nd Audio Engineering Society Convention, Vienna (1992 March) (The use of Ambisonic methods to optimise pan-pot laws for 3- and 4-speaker frontal stage stereo.)
M. A. Gerzon, ‘Hierarchical System of Surround Sound Transmission for HDTV’, Preprint 3339 of the 92nd Audio Engineering Society Convention, Vienna (1992 March) (A proposal for integrating Ambisonics and 5-channel cinema surround sound in a mutually compatible hierarchical system.)
M. A. Gerzon & G. J. Barton, ‘Ambisonic Decoders for HDTV’, Preprint 3345 of the 92nd Audio Engineering Society Convention, Vienna (1992 March) (A new generation of decoders for Ambisonics using more flexible speaker layouts than before, including cinema-type 5 or more speaker layouts. The new decoders give more stable frontal stage images than the 1970's technology did.)
M. A. Gerzon, (Article on Ambisonics, translated into Japanese), presented to the Japan Audio Society, Tokyo (1992 Jun. 6)
M. A. Gerzon, ‘Optimum Reproduction Matrices for Multispeaker Stereo’, J. Audio Engineering Society, vol. 40 no. 7/8, pp. 571-589 (1992 July/August) (A fundamental paper on the application of Ambisonic ideas to frontal stage stereo using more than two loudspeakers. This technology is now known as the ‘Trifield’ system.)
M. A. Gerzon, ‘Hierarchical Transmission System for Multispeaker Stereo’, J. Audio Eng. Soc., vol. 40 no. 9, pp. 692-705 (1992 September) (The design of hierarchical transmission systems for multispeaker frontal stage stereo based on the previous paper.)
M. A. Gerzon, ‘Problems of Upward and Downward Compatibility in Multichannel Stereo Systems’, Preprint 3404 of the 93rd Audio Engineering Society Convention, San Francisco (1992 Oct. 1-4)
M. A. Gerzon, ‘Compatibility of and Conversion Between Multispeaker Systems’, Preprint 3405 of the 93rd Audio Engineering Society Convention, San Francisco (1992 Oct. 1-4)
M. A. Gerzon, ‘Psychoacoustic Decoders for Multispeaker Stereo and Surround Sound’, Preprint 3406 of the 93rd Audio Engineering Society Convention, San Francisco (1992 Oct. 1-4) (A useful up-to-date survey of psychoacoustic decoding of directional sound based on Ambisonic ideas, based on recent work.)
M. A. Gerzon, ‘Signal Processing for Simulating Realistic Stereo Images’, Preprint 3423 of the 93rd Audio Engineering Society Convention, San Francisco (1992 Oct. 1-4) (Use of DSP methods for simulating images realistically placed in a virtual space, including distance and image-size simulation. Based on psychoacoustic methods rather than on physical modelling simulation.)
M. A. Gerzon, ‘Microphone Techniques for 3-Channel Stereo’, Preprint 3450 of the 93rd Audio Engineering Society Convention, San Francisco (1992 Oct. 1-4) (Perhaps the ONLY paper published on recording techniques optimised for 3-channel frontal stereo in the home.)
Ian G. Masters, ‘Ambisonics’, Sound & Vision, Vol. 8, No. 6, 1993 March, pp. 26 & 43.
Richard Elen, article in Audio Media, early 1990s. Complete reference not to hand.
Keith Howard, ‘Meridian Digital theatre system,’ The Gramophone, vol. 72, no. 859, pp. 247 & 250 (1994 December) (review of equipment containing Ambisonic and ‘Trifield’ decoders).
M. A. Gerzon & P. G. Craven, ‘A High-Rate Buried Data Channel for Audio CD’, J. Audio Eng. Soc., vol. 43 No. 1/2 pp. 3-22 (1995 January/February)
A. W. J. Oomen, M. E. Groenewegen, R. G. van der Waal and R. N. J. Veldhuis, ‘A Variable-Bit-Rate Buried-Data Channel for Compact Disc,’ J. Audio Eng. Soc., vol. 43 No. 1/2 pp. 23-28 (1995 January/February)

In a typical application of the Ambisonic system, a Sound Field microphone is used to “sample” the sound field at a venue and transforms this into a standard format of signals which are then supplied to a decoder for driving a plurality of power amplifiers and loudspeakers. When properly decoded and reproduced acoustically, sounds appear to emanate from their positions or directions in the original soundfield relative to the microphone. The decoder is adjusted so as to supply the appropriate signals to any of a large range of physical arrangements of loudspeakers.

### SUMMARY

According to a first aspect of the invention, there is provided a sound feature positioner comprising: a first input for receiving an input signal comprising a plurality of parts representing respective independent sound sources; a first filter connected to the first input and arranged to pass a controllable range of frequencies characteristic of at least one but not all of the parts; and a surround sound encoder for receiving the first filtered signal from the first filter and for encoding the first filtered signal to represent a selected apparent sound source position or direction.

The range of frequencies may be characteristic of one of the parts.

The input signal may be a music signal and each of the parts may represent a musical instrument or a voice.

The first filter may have a bandpass characteristic whose centre frequency is controllable. The first filter may comprise series-connected low pass and high pass filters whose turnover frequencies are controllable.

The positioner may comprise a second filter for reducing the level of the range of frequencies passed by the first filter. The second filter may be connected to the first input for filtering the input signal. As an alternative, the second filter may be connected to a second input for receiving a further input signal comprising at least one part representing a sound source. The further input signal may comprise a plurality of parts representing respective independent sound sources.

The apparent position or direction may be continuously controllable.

The encoder may be an Ambisonic encoder.

The encoder may have a second input connected to the second filter.

The positioner may comprise a surround sound decoder. The positioner may comprise a summer for summing an output signal of the decoder with the input signal. The positioner may comprise a summer for summing an output signal of the decoder with the second filtered signal.

It is thus possible to provide an arrangement which allows a feature, such as a musical feature, to be extracted from a signal which may not contain surround sound information and for the apparent position or direction of the feature to be selected or moved around anywhere within the range of which the surround sound system is capable. For example, in the case of music signals, such an arrangement allows a feature such as an individual musical instrument in a composite signal comprising many musical instruments to be extracted sufficiently well for the sound of the instrument to appear to emanate from any desired point or direction, or for the apparent position or direction of the instrument to be moved intermittently or continuously around the soundfield. Such an arrangement provides an enhanced experience from conventional or non-surround sound signals and may be used, for example, in dance clubs or other venues.

### BRIEF DESCRIPTION OF THE DRAWINGS

FIG. 1 is a block schematic diagram of a surround sound arrangement including a sound feature positioner constituting a first embodiment of the invention;

FIG. 2 is a block schematic diagram of a surround sound arrangement including a sound feature positioner constituting a second embodiment of the invention;

FIG. 3 is a block schematic diagram of a surround sound arrangement including a sound feature positioner constituting a third embodiment of the invention;

FIG. 4 is a block schematic diagram of a surround sound arrangement including a sound feature positioner constituting a fourth embodiment of the invention;

FIG. 5 is a block schematic diagram of a surround sound arrangement including a sound feature positioner constituting a fifth embodiment of the invention; and

FIG. 6 is a block diagram of an encoder in the embodiments of FIGS. 1 to 5.

### DETAILED DESCRIPTION

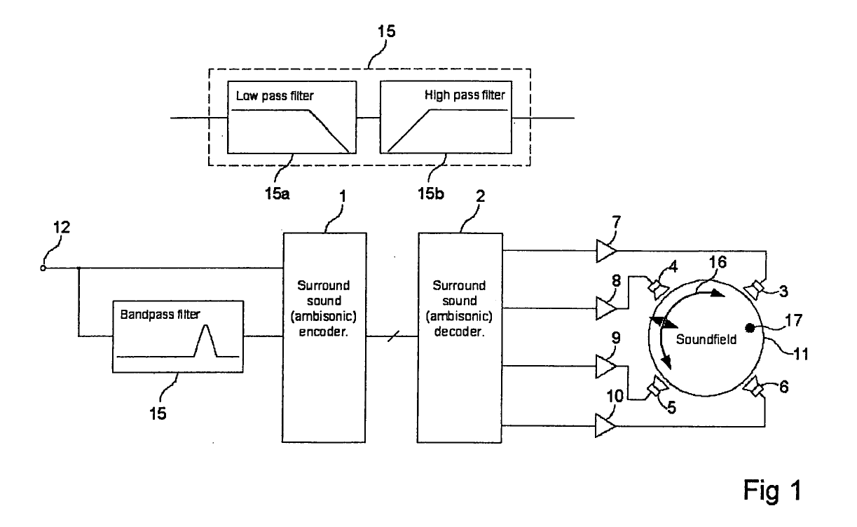

The surround sound system shown in FIG. 1 comprises an Ambisonic encoder 1 connected to an Ambisonic decoder 2. However, other types of surround sound systems may be used and such systems may be of a similar type, in which encoding into standard format signals and decoding for specific loudspeaker arrangements are performed as separate steps or in combination in a single step. In the example illustrated in FIG. 1, the decoder is arranged to drive an array of four loudspeakers 3 to 6 via respective power amplifiers 7 to 10. The decoder 2 is adjusted in accordance with characteristics of the room and the positions of the loudspeakers 3 to 6. In general, the adjustments are performed when the surround sound system is installed in a venue such as a dance club and no further adjustments are then necessary unless or until the loudspeaker array is altered. The soundfield produced by the system is illustrated diagrammatically at 11 and represents the region at the venue within which the apparent positions or directions of sound sources can be perceived. The decoder 2 may be of standard or known type, for example as described in the references which are listed hereinbefore, and which are incorporated herein by reference, and will not be described further.

The encoder 1 is of a type having a plurality of channels (two in this embodiment), each of which is capable of receiving a sound signal such as a music signal and encoding this in accordance with the Ambisonic system so that the apparent position or direction of the sound source as perceived from within the soundfield 11 can be positioned stationarily or moved. An example of the encoder 1 will be described in more detail hereinafter. One of the encoder inputs is connected directly to an input 12 for receiving a signal representing music played by a plurality of instruments and/or voices. The individual instruments and/or voices may be referred to as “parts” and each part represents a sound source which is independent of all of the other sound sources in that its sound is generated independently of the sound generation of the other sound sources and there is no frequency correlation therebetween.

A sound source described as being independent of other sound sources may be understood as representing an individual part of a conventional musical arrangement if the sound sources were to be represented in such a manner. For example, a soprano vocal, a tenor vocal, a piano and a guitar would be considered to be four independent sound sources, represented by four unique parts of a musical arrangement. In the case of computer-generated or otherwise synthesised sound sources, although their generation might not be independent, all occurring within the one medium, different characteristic parts can be represented separately as parts of an arrangement. This therefore also includes the possibility of parts of a part being represented separately as independent sound sources.

In the system shown in FIG. 1, the input signal is supplied directly to the first input of the encoder 1 and via a bandpass filter 15 to a second input of the encoder 1. As shown in the inset of FIG. 1, in this embodiment, the bandpass filter 15 comprises series-connected low pass and high pass filters 15a and 15b. Although the high pass filter 15b is shown as following the low pass filter 15a, this is not important and the low pass filter 15a could equally well follow the high pass filter 15b. As an alternative, any of the filters 15, 15a and 15b may comprise a parametric filter. Also, although the filters 15, 15a and 15b are illustrated as discrete blocks, in practice, these filters may be embodied as analog filters or as digital filters comprising a digital signal processor of any suitable type performing filtering algorithms.

The turnover (−3 dB) frequencies of the filters 15a and 15b are controllable and may track each other or may be independently controllable across the audible frequency spectrum (approximately 15 Hz to approximately 20 KHz) or part thereof so as to provide a bandpass type of characteristic whose centre frequency can be controlled to be at any desired frequency in the audible spectrum and whose passband may also be controlled. For example, the filters 15a and 15b may be of fourth order type with an attenuation which increases at a rate of approximately 24 dB per octave outside the filter passband.

During use of the system, the filter 15 may be adjusted so as to locate and “lock onto” particular instruments or vocal parts occupying specific frequency bands. For example, many instruments are effectively characterised by relatively narrow frequency bands at specific frequencies and the use of the filter 15 allows sufficient of the signal to be passed to characterise the instrument. Although it is not generally possible to exclude contributions from all of the other instruments or voices and although it is not generally possible to capture all of the frequencies generated by the specific instrument (or voice), it has been found that this technique allows the extraction of a signal which characterises an instrument (or voice) and which may be processed using a surround sound system to give the impression that sound from the instrument (or voice) emanates from a position or direction with respect to the soundfield 11, which position or direction may appear to be stationary or may appear to move according to how the encoder 1 is operated. For example, a signal which sufficiently characterises a high-hat may be extracted by the filter 15 and the controls of the encoder 1 may be used to give the impression that the high-hat is revolving in a circle around the soundfield 11, for example as indicated by the double-headed arrow 16. Alternatively, the signal may be located at a selected fixed apparent position in the soundfield, for example as indicated at 17.

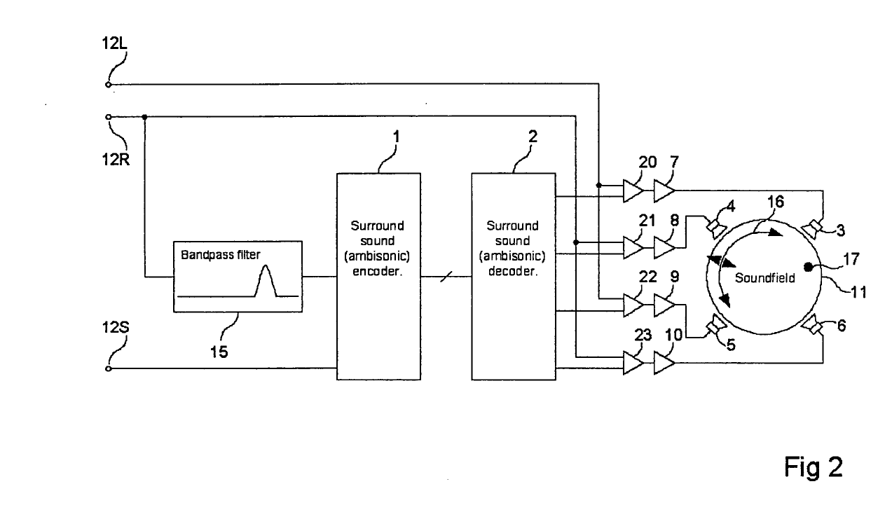

The system illustrated in FIG. 2 differs from that illustrated in FIG. 1 in several respects. Inputs 12L and 12R are provided for conventional left and right signals of a stereo pair and are not supplied to the encoder 1 but, instead, are mixed with output signals of the decoder 2 in summing amplifiers 20 to 23. In the case of the four loudspeaker array illustrated in FIG. 2, the left signals are supplied to a pair of diagonally opposite loudspeakers 3 and 5 whereas the right signals are supplied to the other diagonally opposite loudspeakers 4 and 6. Thus, adjacent pairs of the loudspeakers 3 to 6 carry the left and right stereo signals.

In the specific example shown in FIG. 2, only the right stereo signal from the input 12R is processed by the bandpass filter 15 and supplied to the encoder 1. However, a further filter may receive the signal from the left stereo signal at the input 12L and may supply this to another channel input of the encoder 1. The filtering characteristics of two such filters may be made to track each other or the filters may be controlled entirely independently of each other. Also, further processing of the stereo signals, such as forming sums and/or differences, may be performed before supplying the resulting signal to a filter such as 15.

FIG. 2 also illustrates a further encoder channel input connected to another input 12S for receiving a signal whose apparent or perceived position is to be positioned stationarily or moved with respect to the soundfield 11. The signal supplied to the input 12S may represent a single instrument or voice or a plurality of instruments and/or voices and may comprise a mono signal, for example from a microphone.

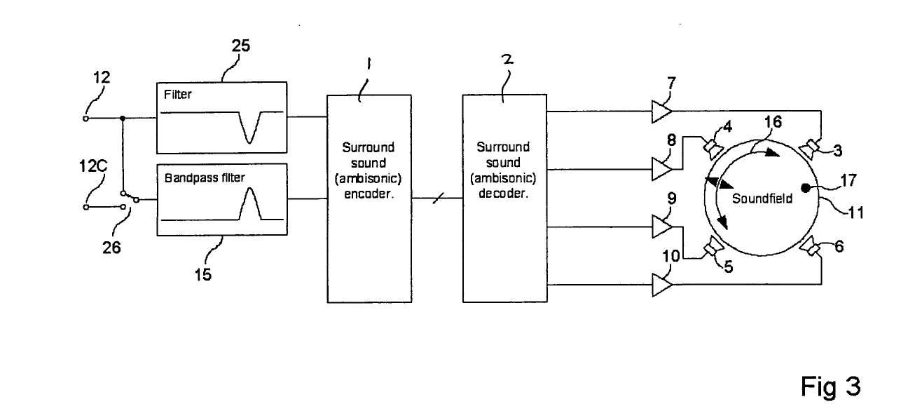

The system shown in FIG. 3 differs from that shown in FIG. 1 in that the signal supplied to the input 12, such as one channel of a stereo pair, is supplied to the encoder 1 via a notch or bandstop filter 25. The notch or bandstop filter 25 reduces or attenuates the band of frequencies which are selected by the bandpass filter 15 so that the centre frequency (and width) of the notch or stopband tracks the centre frequency (and width) of the passband. For example, the filter 25 may be embodied as paralleled and summed high pass and low pass filters of the same type as the filters 15a and 15b.

The filter 25 may be thought of as creating a frequency and musical “space” for the “dynamic” feature extracted by the filter 15 to occupy. Also, the use of the filter 25 may serve to restore the frequency balance in the soundfield 11. The “depth” of the stopband may be equal to the “height” of the peak or may be less than this. For example, if the “main music signal” supplied via the notch filter 25 is being reproduced by several or all of the loudspeakers 3 to 6 whereas the feature extracted by the filter 15 is being reproduced by fewer of the loudspeakers 3 to 6, the loudness of the extracted feature may be perceived as being more naturally balanced, for example when the depth of the notch is less than the height of the peak.

FIG. 3 also illustrates a changeover switch 26 to allow the input of the bandpass filter 15 to be connected either to the input 12 or to another input 12C for receiving another signal comprising a plurality of parts representing independent sound sources, such as another music signal comprising a plurality of instruments and/or voices. The signal supplied to the input 12C may be related to that supplied to the input 12, for example in the case of a stereo pair of signals, or may be entirely independent, for example to allow a feature extracted from a different piece of music to be placed or moved in or with respect to the soundfield 11.

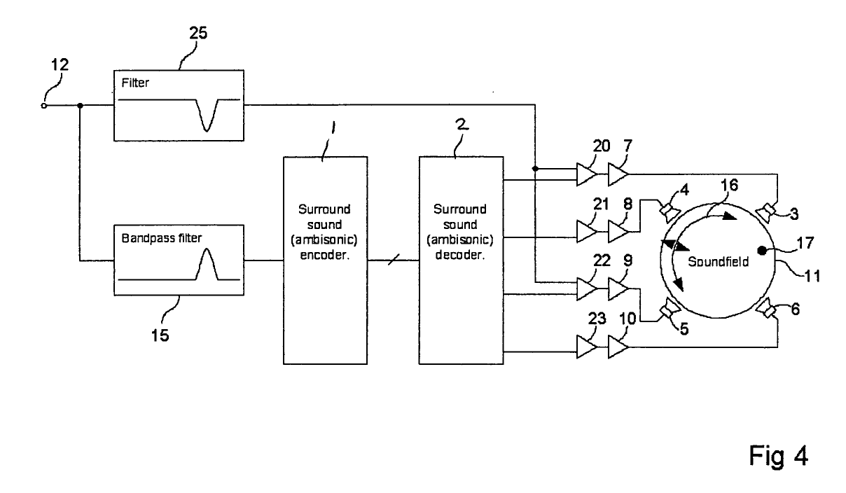

The system shown in FIG. 4 differs from that shown in FIG. 3 in that the “main music signal” from the filter 25 bypasses the surround sound encoder 1 and decoder 2 and is mixed with outputs of the decoder 2 in the same way as illustrated in FIG. 2.

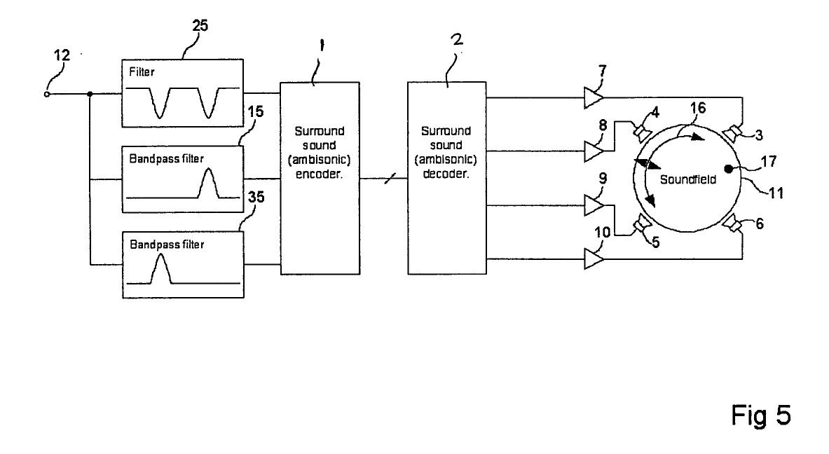

The system shown in FIG. 5 differs from that shown in FIG. 3 in that a further bandpass filter 35 is connected between the input 12 and a third channel of the encoder 1. Also, the filter 25 provides a stopband corresponding to the passband of each of the filters 15 and 35. This arrangement allows two features to be extracted from the music signal and to be processed independently by the encoder 1 so that the apparent positions of the sound features can be positioned and/or moved, independently of each other, in or with respect to the soundfield 11.

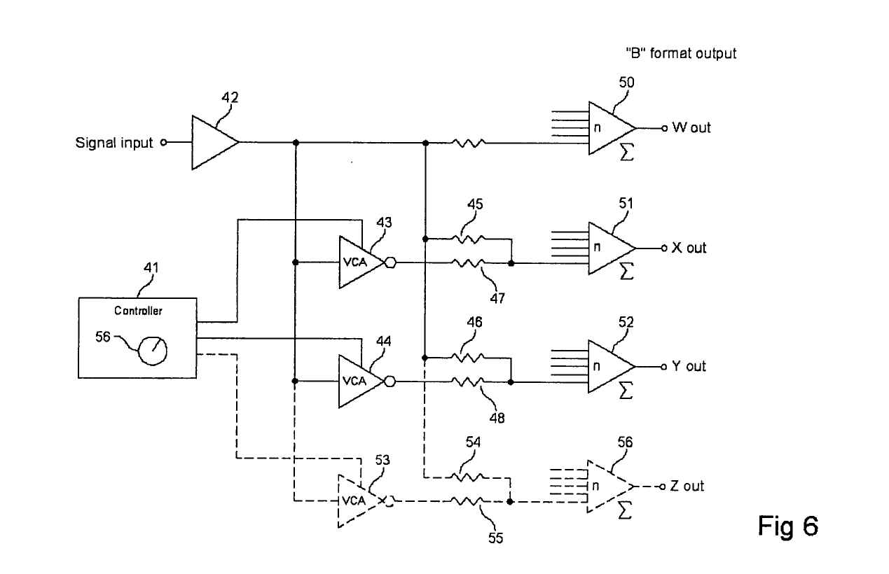

FIG. 6 illustrates a typical example of an Ambisonics encoder 1 which is suitable for use in the arrangements shown in FIGS. 1 to 5. FIG. 6 illustrates a single input channel controlled by a controller 41 but any desired number of such channels of the same or similar type may be provided with their own controllers or controlled by the controller 41.

The controller 41 is illustrated as having a manually operable control 56 and may comprise an arrangement which converts the output signals of a joystick, mouse or other suitable manually operable control directly into voltages for controlling the VCAs 43 and 44. Alternatively or additionally, the controller 41 may be arranged to supply control voltages which are programmed, derived or generated in any suitable way so as to position or move the apparent location or direction of a sound source with respect to the sound field.

The signal input is supplied to a buffer 42, whose output is connected to the inputs of voltage controlled amplifiers (VCAs) 43 and 44 and via resistors 45 and 46 to summing nodes of output amplifiers 51 and 52, respectively. The outputs of the amplifiers 43 and 44 are also supplied via resistors 47 and 48 to the summing nodes of the amplifiers 51 and 52, respectively. The amplifiers 43 and 44 are inverting amplifiers and their gains are controllable from 0 to ×2 in accordance with control signals supplied by the controller 41.

In the example illustrated, the apparent location or direction of the sound source is controllable in a horizontal plane so that it is only necessary for the W, X and Y “B” format Ambisonic components to be derived from the input signal. However, if encoding of height information is also required, then a Z component can be derived and an arrangement for providing this is illustrated in broken lines by the amplifier 53, the resistors 54 and 55, and the output amplifier 56. An output amplifier 50 is illustrated for providing the W component.

Each of the summing amplifiers 50 to 52 and 56 is illustrated as having n inputs for receiving other signals to be encoded in the “B” Ambisonic format. The amplifiers provide “B” format output signals Wout, Xout, Yout and (optionally) Zout and the signals are supplied to the decoder 2 for driving the loudspeaker array in accordance with conventional Ambisonic techniques.

Although the embodiments described hereinbefore have been illustrated as analogue electronic embodiments, some or all of the elements of the systems may be embodied digitally. For example, the input signals to the system may be digital or may be converted to digital signals and all of the signal processing may be performed in the digital domain, for example in one or more digital signal processing integrated circuits.

The embodiments described hereinbefore have used Ambisonic encoding to allow the apparent location or direction of a sound source to be controlled. However, other encoding techniques may be used and may employ different “panning laws” for controlling how the sound is processed in order for it to appear to emanate from a controllable location or direction. For example, in accordance with another panning law, if it is desired for the sound source to appear to emanate from the centre of the soundfield 11, the signal extracted by the filter 15 may be supplied at the same level to all of the speakers. If the sound is to emanate from a point between the edge and the centre of the soundfield 11, this may be achieved by crossfading between the “balance” for the centre position and a balance for an edge position. If the sound is to appear to emanate from the edge of the soundfield in the case of a four loudspeaker system as illustrated in the drawings, then the relative levels will depend on the desired location. For example, if the sound is to appear to emanate from the location of one of the loudspeakers, the adjacent loudspeaker will receive the maximum level, the opposite loudspeaker will receive zero level, and the other loudspeakers will receive the same level between zero and the maximum level. If the sound is to appear to emanate from the midpoint between two loudspeakers at the edge of the soundfield, the adjacent loudspeakers will receive almost the maximum level and the other loudspeakers will receive almost zero level.

1. A sound feature positioner comprising: a first input for receiving an input signal comprising a plurality of parts representing respective independent sound sources; a first filter for supplying a first filtered signal, said first filter being connected to said first input and being arranged to pass a controllable range of frequencies characteristic of at least one but not all of said parts; and a surround sound encoder for receiving said first filtered signal from said first filter and for encoding said first filtered signal to represent one of a selected apparent sound source position a selected apparent sound source direction.

2. A positioner as claimed in claim 1, in which said range of frequencies is characteristic of one of said parts.

3. A positioner as claimed in claim 1, in which said input signal is a music signal and each of said parts represents one of a musical instrument and a voice.

4. A positioner as claimed in claim 1, in which said first filter has a bandpass characteristic having a centre frequency which is controllable.

5. A positioner as claimed in claim 4, in which said first filter comprises series-connected low pass and high pass filters having turnover frequencies which are controllable.

6. A positioner as claimed in claim 1, comprising a second filter for supplying a second filtered signal and for reducing a level of said range of frequencies passed by said first filter.

7. A positioner as claimed in claim 6, in which said second filter is connected to said first input for filtering said input signal.

8. A positioner as claimed in claim 6, comprising a second input for receiving a further input signal comprising at least one further part representing a further sound source, said second filter being connected to said second input.

9. A positioner as claimed in claim 8, in which said further input signal comprises a plurality of further parts representing respective independent further sound sources.

10. A positioner as claimed in claim 1, in which said one of said apparent position and said apparent direction is continuously controllable.

11. A positioner as claimed in claim 10, comprising a second filter for supplying a second filtered signal and for reducing a level of said range of frequencies passed by said first filter, said encoder having a second input connected to said second filter.

12. A positioner as claimed in claim 1, in which said encoder is an Ambisonic encoder.

13. A positioner as claimed in claim 12, comprising a second filter for supplying a second filtered signal and for reducing a level of said range of frequencies passed by said first filter, said encoder having a second input connected to said second filter.

14. A positioner as claimed in claim 1, comprising a surround sound decoder.

15. A positioner as claimed in claim 14, comprising a summer for summing an output signal of said decoder with said input signal.

16. A positioner as claimed in claim 14, comprising: a second filter for supplying a second filtered signal and for reducing a level of said range of frequencies passed by said first filter; and a summer for summing an output signal of said decoder with said second filtered signal.
